(19) United States
(12) Patent Application Publication
(10) Pub. No.: US 2015/0349016 A1
(43) Pub. Date: Dec. 3, 2015

(54) IMAGE SENSOR FOR X-RAY AND METHOD OF MANUFACTURING THE SAME

(71) Applicant: SILICON DISPLAY TECHNOLOGY, Yongin-si, Gyeonggi-do (KR)

(72) Inventors: Yong Ju HAM, Bucheon-si (KR); Ji Ho HUR, Yongin-si (KR); Ki Joong KIM, Suwon-si (KR); Youn Duck NAM, Gwangmyeong-si (KR); Soon Ho CHOI, Yongin-si (KR)

(21) Appl. No.: 14/760,858

(22) PCT Filed: Sep. 30, 2013
(86) PCT No.: PCT/KR2013/008756

§ 371 Date: Jul. 14, 2015

(30) Foreign Application Priority Data
Jan. 17, 2013 (KR) 10-2013-0005452

(51) Int. Cl. H01L 27/146; H01L 31/20; H01L 29/66; H01L 29/786; H01L 29/24

(52) U.S. Cl. CPC H01L 27/14658; H01L 29/78693; H01L 29/24; H01L 27/14612; H01L 27/14636; H01L 27/14689; H01L 29/66969; H01L 31/20

(57) ABSTRACT

Provided are an image sensor for an X-ray and a method of manufacturing the same, the image sensor for the X-ray, including: a semiconductor active layer formed on an insulating substrate; a gate insulating film on the semiconductor active layer; a gate electrode formed on the gate insulating film; an interlayer insulating film which is formed on the gate electrode and in which a first via hole is formed; a source electrode formed on the first via hole; a drain electrode formed on the first via hole; a first electrode formed to be connected to the source electrode or the drain electrode; and a photo diode formed on the first electrode.

### TECHNICAL FIELD

Embodiments of the present invention relate to an image sensor for an X-ray and a method of manufacturing the same, and more particularly, to an image sensor for an X-ray and a method of manufacturing the same, which can compensate the disadvantages of a conventional manufacturing process by changing a structure of a thin film transistor, and can increase the degree of integration by reducing the size of a device.

### BACKGROUND ART

In a diagnostic X-ray inspection method which has been currently widely used for medical purposes, photographing is performed using an X-ray sensing film, and a predetermined time to print images of the film is required in order to check a result of the photographing.

However, an image sensor for an X-ray using a thin film transistor thanks to the development of a semiconductor technology has been recently developed. As the thin film transistor as a switching element is used in the image sensor for the X-ray, the image sensor is advantageous in that the result of X-ray imaging can be diagnosed in real time immediately when the result of X-ray imaging is performed.

The image sensor for the X-ray is gradually pursuing high resolution and low noise. In order for the image sensor for the X-ray to reduce noise while maintaining high resolution, a turn-off current and a photo-leakage current of a thin film transistor should be reduced. Although an amorphous silicon thin transistor, which has been mainly used, has a low leakage current, since it sensitively operates according to a back channel etching process, there is a need to perform an additional process.

Also, since the amorphous silicon thin transistor has a low field-effect mobility of about 0.5/Vs, it should have a W/L of more than 25/5. Due to this, a parasitic capacitance increases, and thus this becomes a factor which causes an increase in image noise of the image sensor.

Furthermore, since the amorphous silicon thin film transistor has no a high photo-leakage current in a visible light area, a barrier layer, which blocks light, is required, and due to this, a parasitic capacitance increases. Furthermore, as a fill factor of a photo diode is reduced, this becomes a factor which causes a reduction in signal to noise ratio (the S/N ratio).

On the other hand, when a polycrystalline silicon thin film transistor is used, since it has a high field-effect mobility, the parasitic capacitance can be reduced. However, in order to form a device having a low turn-off current, a process becomes complicated, and a process cost increases.

To solve such a problem, in to the conventional art, the oxide thin film transistor is configured in a coplanar structure, but since an X-ray sensor having the inverted coplanar structure is configured such that a gate electrode is located below a semiconductor active layer, self alignment for gate, source and drain electrodes cannot be not performed. Furthermore, after a process for a semiconductor active layer is performed, a process for a protective layer of the active layer should be additionally performed, and a pixel size could not be reduced beyond a certain level because the size of a device is large in light of a characteristic of the corresponding structure. In addition to this, since the semiconductor active layer is located above the gate electrode, X-rays and UV rays irradiated to the photo diode pass through the semiconductor active layer, and as a result, this has a harmful influence on the oxide semiconductor active layer.

On the other hand, in general, when the active layer of the thin film transistor is configured of an oxide semiconductor, safety of the semiconductor active layer and reproducibility in quality are reduced, and thus it would be difficult to utilize it as a semiconductor device. The reason is because plasma generated at the time of forming the gate insulating film after forming the semiconductor active layer with an oxide has a harmful influence on the semiconductor active layer, it would be difficult to form a normal semiconductor active layer. Accordingly, in order to overcome the problems as described above, the development of a technology capable of improving the problems by specializing process conditions and environments has been required.

### DISCLOSURE

### Technical Problem

Accordingly, the present invention has been made keeping in mind the above problems occurring in the related art. An aspect of embodiments of the present invention provides an image sensor for an X-ray and a method of manufacturing the same, in which an oxide thin film transistor is configured in an inverted coplanar structure, which can compensate disadvantages of the inverted coplanar structure is compensated by specializing process conditions at the time of forming a semiconductor active layer with an oxide and formation condition of a gate insulating film, and which can solve a problem such as non-reproducibility that is unique to the oxide semiconductor.

### Technical Solution

According to an aspect of one embodiment of the present invention, there is provided an image sensor for an X-ray, including: a semiconductor active layer formed on an insulating substrate; a gate insulating film on the semiconductor active layer; a gate electrode formed on the gate insulating film; an interlayer insulating film which is formed on the gate electrode and in which a first via hole is formed; a source electrode formed on the first via hole; a drain electrode formed on the first via hole; a first electrode formed to be connected to the source electrode or the drain electrode; and a photo diode formed on the first electrode.

According to another embodiment of the present invention, the photo diode may include: a semiconductor layer formed on the first electrode; a second electrode formed on the semiconductor layer; and a common electrode formed to be connected to the second electrode.

According to still another embodiment of the present invention, the image sensor may further include a buffer film formed between the insulating substrate and the semiconductor active layer.

According to still further another embodiment of the present invention, the image sensor may further include an insulating layer which is formed on the source electrode and the drain electrode and in which a second via hole is formed, and the first electrode may be formed to be connected to the source electrode or the drain electrode via the second via hole.

According to still further another embodiment of the present invention, the semiconductor active layer may be formed of any one of ZnO (Zinc Oxide), GZO (Gallium Zinc Oxide), IZO (Indium Zinc Oxide), ITO (Indium Tin Oxide), and IGZO (Indium Gallium Zinc Oxide).

According to still further another embodiment of the present invention, the semiconductor active layer may be formed in an amorphous structure.

According to still further another embodiment of the present invention, the semiconductor active layer may be formed in a thickness of 5 nm to 10 nm.

According to still further another embodiment of the present invention, the gate insulating film may be composed of a silicon oxide film.

According to still further another embodiment of the present invention, the gate insulating film may be formed in the same size as that of the gate electrode.

According to still further another embodiment of the present invention, the buffer film may be formed of any one of a silicon oxide film, a silicon oxynitride film and a silicon nitride film, or a mixture formed of at least two of them.

According to still further another embodiment of the present invention, the insulating substrate may be formed by coating an insulating film on an insulating material substrate or a metallic substrate.

According to still further another embodiment of the present invention, the semiconductor layer of the photo diode may include a P-type semiconductor layer, an intrinsic semiconductor layer and an N-type semiconductor layer.

According to still further another embodiment of the present invention, the semiconductor layer of the photo diode may be composed of amorphous silicon.

According to an aspect of one embodiment of the present invention, there is provided a method of manufacturing an image sensor for an X-ray, the method including: forming a semiconductor active layer on an insulating substrate; forming a gate insulating film on the semiconductor active layer; forming a gate electrode on the gate insulating film; forming an interlayer insulating film on the gate electrode and forming a first via hole in the interlayer insulating film; forming a source electrode and a drain electrode on the first via hole; forming a first electrode connected to the source electrode or the drain electrode; and forming a photo diode on the first electrode.

According to another embodiment of the present invention, the forming of the photo diode on the first electrode may include: forming a semiconductor layer on the first electrode; forming a second electrode on the semiconductor layer; and forming a common electrode to be connected to the second electrode.

According to still another embodiment of the present invention, the forming of the semiconductor active layer on the insulating substrate may include: forming a buffer film on the insulating substrate; and forming the semiconductor active layer on the buffer film.

According to still further another embodiment of the present invention, the forming of the semiconductor active layer on the insulating substrate may further include thermally treating the semiconductor active layer within any one of oxygen gas, nitrogen gas, helium gas and argon gas, or within a mixed gas formed of at least two of them at a temperature of 200 to 600.

According to still further another embodiment of the present invention, the forming of the gate insulating film on the semiconductor active layer may include: forming a protective layer made of the same material as that of the gate insulating film in an upper part of the semiconductor active layer; and forming the gate insulating film in an upper part of the protective layer.

According to still further another embodiment of the present invention, the method of manufacturing the image sensor may further include: forming an insulating layer on the source electrode and the drain electrode, and forming a second via hole in the insulating layer.

According to still further another embodiment of the present invention, the forming of the first electrode connected to the source electrode or the drain electrode may be performed by forming the first electrode to be connected the source electrode or the drain electrode via the second via hole.

According to still further another embodiment of the present invention, the gate insulating film may be formed in the same size as that of the gate electrode.

### Advantageous Effects

According to the embodiments of the present invention, in the method of manufacturing the image sensor for the X-ray, as the oxide thin film transistor is configured in a coplanar structure, and an etch stopper process, which is necessary at the time of manufacturing it in an inverted coplanar structure, is removed, the manufacturing process can be simplified and a production cost and a manufacturing time can be reduced.

Meanwhile, as quality of the semiconductor active layer can be improved by thermally treating the semiconductor active layer at a specified gas condition after forming the semiconductor active layer, stability of the process, which will be performed later, can be secured.

According to the embodiments of the present invention, under the condition that the amount of plasma generated at the time of forming the gate insulating film is small, after the protective layer made of the same material as that of the gate insulating film is first formed to be thin, the gate insulating film having high quality is additionally formed, thereby preventing the semiconductor active layer from being damaged by the plasma generated at the time of forming of the gate insulating film.

Also, according to the embodiments of the present invention, as the gate insulating layer is patterned to be identical to the gate electrode so that the gate electrode can serve as a mask, the semiconductor active layer is influenced by the plasma during a dry etching process. Thus, a self-align technology which enables the gate, source and drain to be automatically aligned can be applied. Compared to the conventional structure of the thin film transistor, a channel length of the thin film transistor can be innovatively reduced, and the degree of integration of the image sensor can be improved according to a reduction in size of the device.

Also, according to the embodiments of the present invention, since the gate electrode is located at a higher place than the semiconductor active layer, the semiconductor active layer can be prevented from being damaged by X-rays or UV rays irradiated from the top.

### DESCRIPTION OF DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a circuit view showing a pixel of an image sensor for an X-ray according to one embodiment of the present invention;

FIG. 2 is a cross-sectional view of the image sensor for the X-ray according to the one embodiment of the present invention;

FIG. 3 through FIG. 5 are views illustrating a method of manufacturing the image sensor for the x-ray according to the one embodiment of the present invention;

FIG. 6 is a cross-sectional view of an image sensor for an X-ray according to another embodiment of the present invention;

FIG. 7 through FIG. 9 are views illustrating a method of manufacturing the image sensor for the X-ray according to the other embodiment of the present invention;

FIG. 10 is a cross-sectional view of an image sensor for an X-ray according to still another embodiment of the present invention; and

FIG. 11 through FIG. 13 are views illustrating a method of manufacturing the image sensor for the X-ray according to the still another embodiment of the present invention.

### BEST MODE

Hereinafter, embodiments of the present invention will be described in detail with reference to the accompanying drawings. In the following description, it is to be noted that, when the functions of conventional elements and the detailed description of elements related with the present invention may make the gist of the present invention unclear, a detailed description of those elements will be omitted. Further, it should be understood that the shape and size of the elements shown in the drawings may be exaggeratedly drawn to provide an easily understood description of the structure of the present invention rather than reflecting the actual sizes of the corresponding elements.

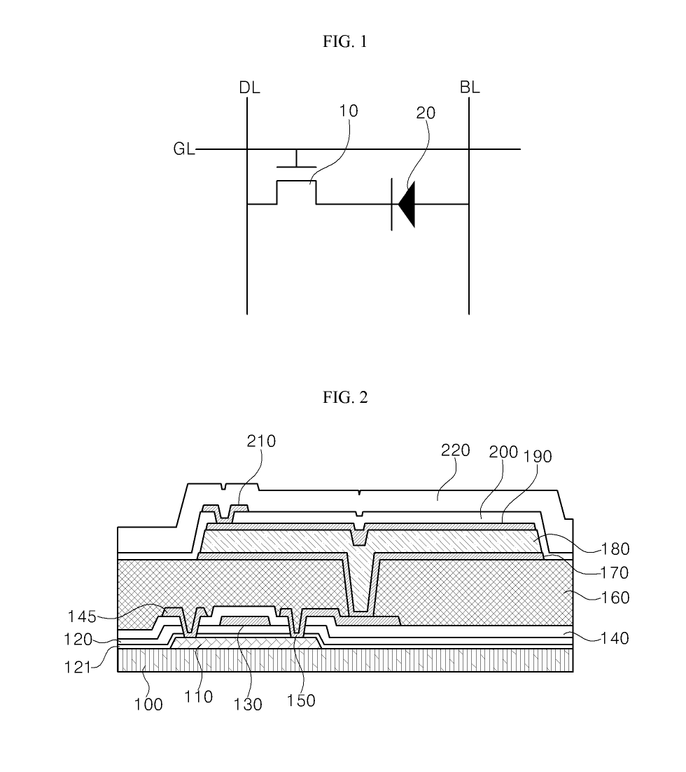

FIG. 1 is a circuit view showing a pixel of an image sensor for an X-ray according to one embodiment of the present invention, and FIG. 2 is a cross-sectional view of the image sensor for the X-ray according to the one embodiment of the present invention.

The configuration of an image sensor for an X-ray according to the present embodiment of the invention will be explained with reference to FIG. 1 and FIG. 2.

As illustrated in FIG. 1, a pixel of the image sensor for the X-ray includes; a gate line GL and a data line DL; a thin film transistor 10 connected to the gate line GL and the data line DL; a bias power supply line BL that crosses the gate line GL and is formed to be aligned with the data line DL; and a photo diode 20 connected to the thin film transistor 10 and the bias power supply line BL.

As illustrated in FIG. 2, the thin film transistor 10 is connected to the gate line GL, and the image sensor includes: a semiconductor active layer 110 formed on an insulating substrate 100; a gate insulating film 120 formed in an upper part of the semiconductor active layer 110 to cover the semiconductor active layer 110; a gate electrode 130 formed on the gate insulating film 120; an interlayer insulating film formed on the gate electrode 130; a source electrode 145 and a drain electrode 150 formed on a first via hole of the interlayer insulating film 140; a first electrode 170 formed to be connected to the source electrode 145 or the drain electrode 150; and a photo diode formed on the first electrode 170.

At this time, in the embodiment of FIG. 2, an insulating layer 160 is formed on the source electrode 145 and the drain electrode 150, and a second via hole is formed in the insulating layer 160. Accordingly, the first electrode 170 of the photo diode is configured to be connected to the source electrode 145 or the drain electrode 150 via the second via hole.

At this time, a buffer film may be further formed between the insulating substrate 100 and the semiconductor active layer 110.

Also, the insulating substrate 100 may be formed by coating an insulating film on an insulating material substrate or a metal substrate, and the semiconductor active layer 110 may be formed in an amorphous structure and in a thickness of 5 nm to 10 nm.

Also, after the semiconductor active layer 110 is formed, the semiconductor active layer 110 is thermally treated within any one of oxygen gas, nitrogen gas, helium gas and argon gas, or within a mixed gas formed of at least two of them at a temperature of 200 to 600. Through this process, quality of the semiconductor active layer is improved, thereby securing safety of the process which will be performed later.

Furthermore, the gate insulating film 120 may be made of a silicon oxide film, and the buffer film may be made of any one of a silicon oxide film, a silicon oxynitride film and a silicon nitride film, or a mixture formed at least two of them.

At this time, when the gate insulating film 120 is formed on the semiconductor active layer 110, a protective layer 121 made of the same material as that of the gate insulating film 120 may be formed in an upper part of the semiconductor active layer, and the gate insulating film 120 may be formed in an upper part of the protective layer 121.

As such, when the protective layer 121 is formed, the semiconductor active layer can be prevented from being damaged by plasma generated at the time of forming the gate insulating film 120. Meanwhile, when the protective layer 121 is formed, the generation amount of plasma can be reduced by adjusting the RF (Radio Frequency) power of CVD (chemical vapor deposition) to be low.

Meanwhile, the photo diode may include: a semiconductor layer 180 formed on the first electrode 170; a second electrode 190 formed on the semiconductor layer 180; a first protective film 200 formed on the second electrode 190; and a common electrode 210 formed to be connected to the second electrode 190, and a second protective film 220 may be configured in an upper part of the first protective film 200 and the common electrode 210.

At this time, the semiconductor layer 190 of the photo diode may be composed of amorphous silicon, and may include: a P-type semiconductor layer, an intrinsic semiconductor layer, and an N-type semiconductor layer.

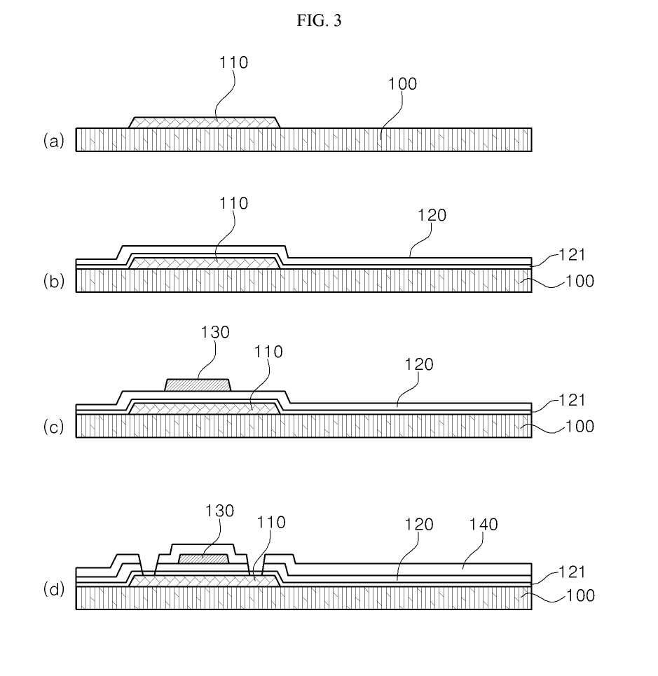

FIG. 3 through FIG. 5 are views illustrating a method of manufacturing the image sensor for the x-ray according to the one embodiment of the present invention;

A method of manufacturing the image sensor for the X-ray according to the one embodiment of the present invention will be hereinafter explained with reference to FIG. 3 to FIG. 5.

When manufacturing the image sensor for the X-ray according to the one embodiment of the present invention, as illustrated in (a) of FIG. 3, the semiconductor active layer 110 is formed on the insulating substrate 100, and as illustrated in (b) of FIG. 3, the gate insulating film 120 is formed on the semiconductor active layer 110 and the insulating substrate 100.

At this time, after the semiconductor active layer 110 is formed, the semiconductor active layer 110 is thermally treated within any one of oxygen gas, nitrogen gas, helium gas and argon gas, or within a mixed gas formed of at least two of them at a temperature of 200 to 600. Through this process, quality of the semiconductor active layer is improved, thereby securing safety of the process which will be performed later.

When the gate insulating film 120 is formed on the semiconductor active layer 110, the protective layer 121 made of the same material as that of the gate insulating film 120 may be formed in the upper part of the semiconductor active layer, and the gate insulating film 120 may be formed in the upper part of the protective layer 121.

As such, when the protective layer 121 is formed, the semiconductor active layer can be prevented from being damaged by the plasma generated at the time of forming the gate insulating film 120. Meanwhile, when the protective layer 121 is formed, the generation amount of plasma may be reduced by adjusting the RF power of the CVD to be low. After this, as illustrated in (c) of FIG. 3, the gate electrode 130 is formed on the gate insulating film 120, and as illustrated in (d) of FIG. 3, the interlayer insulating film 140 is formed on the gate electrode 130, and the first via hole is formed in the interlayer insulating film 140. At this time, the first via hole is formed to pass through the gate insulating film 120 so that an upper surface of the semiconductor active layer 110 is exposed.

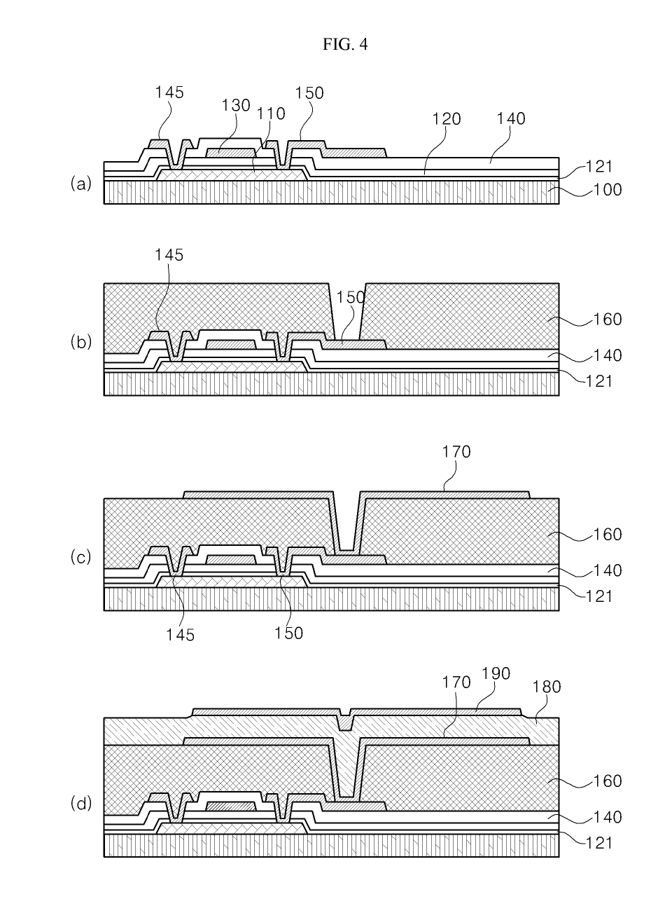

As illustrated in (a) of FIG. 4, the source electrode 145 and the drain electrode 150 are formed on the first via hole formed as above, and as illustrated in (b) of FIG. 4, the insulating layer 160 is formed on the source electrode 145 and the drain electrode 150, the second via hole is formed in the insulating layer 160 formed as above so that an upper part of the source electrode 145 or the drain electrode is exposed by the second via hole.

After this, as illustrated in (c) of FIG. 4, the first electrode 170 connected to the source electrode 145 or the drain electrode 170 is formed on the insulating layer 160.

As illustrated in (d) of FIG. 4, the semiconductor layer 180 is formed on the first electrode 170, and the second electrode 190 is again formed in the upper part of the semiconductor layer 180.

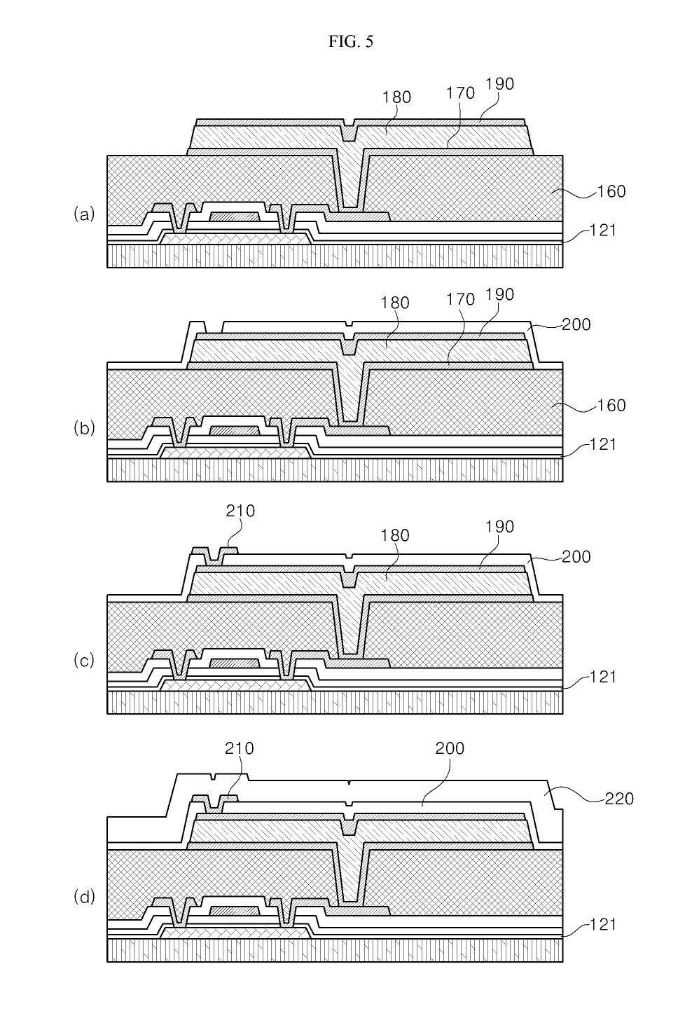

After this, as illustrated in (a) of FIG. 5, the semiconductor layer 180 is patterned, and as illustrated in (b) of FIG. 5, the first protective film 200 is formed in an upper part of the second electrode 190.

Also, as illustrated in (c) of FIG. 5, the common electrode 210 is formed on the first protective film 200, and as illustrated in (d) of FIG. 5, the second protective film 220 is again formed in an upper part of the common electrode 210.

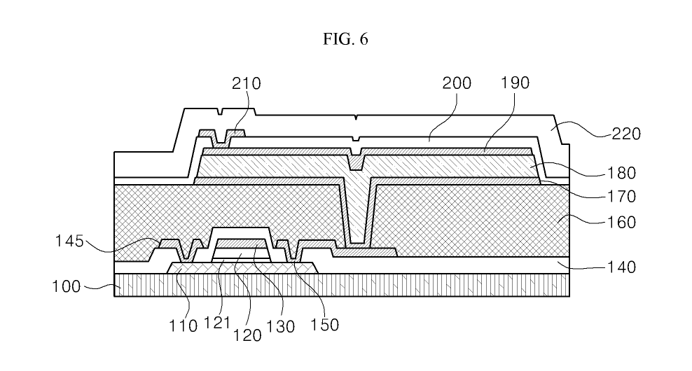

FIG. 6 is a cross-sectional view of an image sensor for an X-ray according to another embodiment of the present invention.

As illustrated in FIG. 6, an image sensor for an X-ray according to another embodiment of the present invention may be configured to include: the semiconductor active layer 110 formed on the insulating substrate 100; the gate insulating film 120 formed to cover the semiconductor active layer 110; the gate electrode 130 formed on gate insulating film 120 in the same form as the gate insulating film 120; the interlayer insulating film 140 formed on the gate electrode 130; the source electrode and the drain electrode 150 on the first via hole of the interlayer insulating film 140; the first electrode 170 formed to be connected to the source electrode 145 or the drain electrode; and the photo diode formed on the first electrode 170.

That is, the embodiment of FIG. 6 compared to the embodiment of FIG. 5 has a difference that the gate electrode 130 and the gate insulating film 120 are formed in the same size as each other.

At this time, when the gate insulating film 120 is formed on the semiconductor active layer 110, the protective layer 121 made of the same material as the gate insulating film 120 may be formed in the upper part of the semiconductor active layer, and the gate insulating film 120 may be formed in the upper part of the protective layer 121.

Also, in the embodiment of FIG. 6, the insulating layer 160 is formed on the source electrode 145 and the drain electrode 150, and the second via hole is formed in the insulating layer 160. Accordingly, the first electrode 170 is connected to the source electrode 145 or the drain electrode 150 via the second via hole.

At this time, the buffer film may be further formed between the insulating substrate 100 and the semiconductor active layer 110, the insulating substrate 100 may be formed by coating an insulating film on an insulating material substrate or a metal substrate, and the semiconductor active layer 110 may be formed in an amorphous structure and in a thickness of 5 nm to 100 nm. Also, the gate insulating film 120 may be made of a silicon oxide film, and the buffer film may be made of any one of a silicon oxide film, a silicon oxynitride film and a silicon nitride film, or a mixture formed of at least two of them.

Like the embodiment of FIG. 2, the photo diode may be configured to include: the semiconductor layer 180 formed on the first electrode 170; the second electrode 190 formed on the semiconductor layer 180; the first protective film 200 formed on the second electrode 190; and the common electrode 210 formed to be connected to the second electrode 190, and the second protective film 220 may be again formed in the upper part of the first protective film 200 and the common electrode 210. At this time, the semiconductor layer 180 of the photo diode may be made of amorphous silicon, and may be configured to include the P-type semiconductor layer, the intrinsic semiconductor layer and the N-type semiconductor layer.

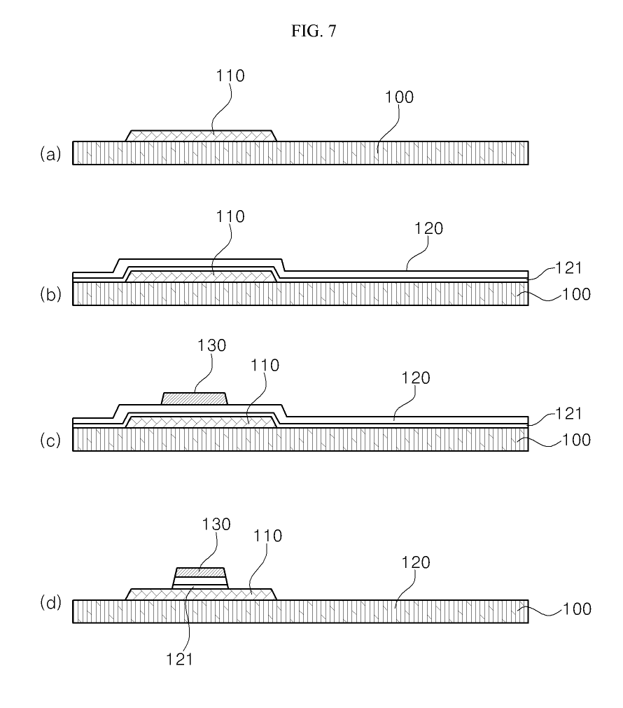

FIG. 7 through FIG. 9 are views illustrating a method of manufacturing the image sensor for the X-ray according to the other embodiment of the present invention.

Hereinafter, a method of manufacturing the image sensor for the X-ray according to the other embodiment of the present invention will be explained with reference to FIG. 7 to FIG. 9.

First, as illustrated in (a) of FIG. 7, the semiconductor active layer 110 is formed on the insulating substrate 100, and as illustrated in (b) of FIG. 7, the gate insulating film 120 is formed on the semiconductor active layer 110 and the insulating substrate 100.

At this time, when the gate insulating film 120 is formed on the semiconductor active layer 110, the protective layer 121 made of the same material as that of the gate insulating film 120 may be formed in the upper part of the semiconductor active layer 110, and the gate insulating film 120 may be formed in the upper part of the protective layer 121.

After this, as illustrated in (c) of FIG. 7, the gate electrode 130 is formed on the gate insulating film 120, and as illustrated in (d) of FIG. 7, the gate insulating film 120 is patterned.

At this time, the gate insulating film 120 is patterned in the same size as that of the gate electrode 130.

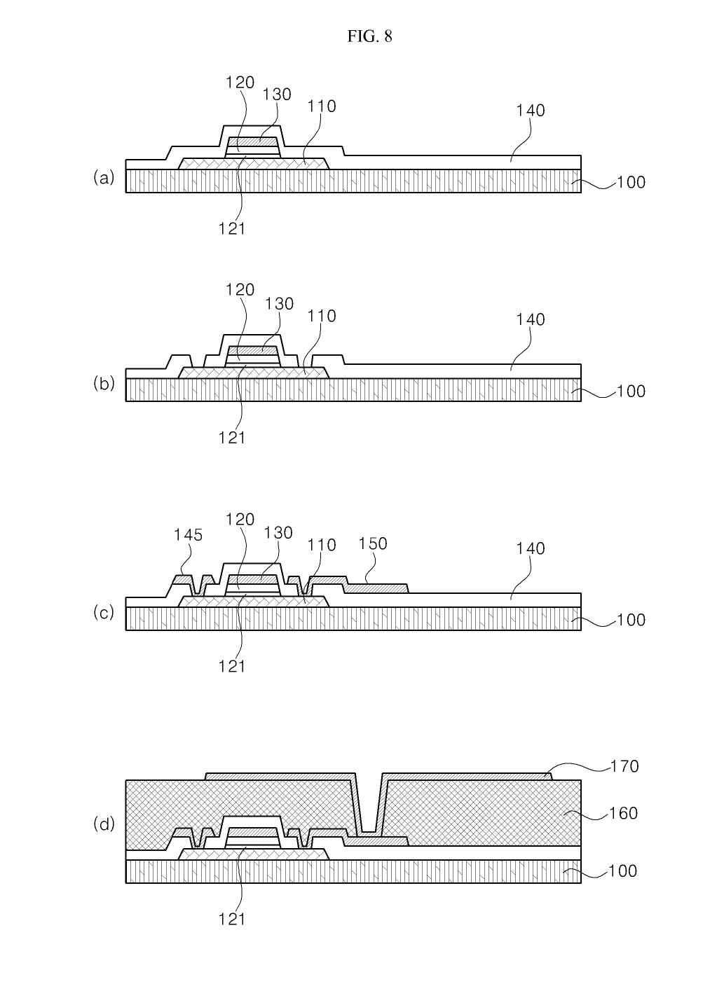

As illustrated in (a) of FIG. 8, the interlayer insulating film 140 is formed in an upper part of the gate electrode 130, and as illustrated in (b) of FIG. 8, the first via hole is formed in the interlayer insulating film 140, and as a result, the upper surface of the semiconductor active layer 110 is exposed by the first via hole.

As illustrated in (c) of FIG. 8, the source electrode 145 and the drain electrode 150 are formed on the first via hole formed as above, and as illustrated in (d) of FIG. 8, the insulating layer 160 is formed on the source electrode 145 and the drain electrode 150, and the second via hole is formed in the insulating layer 160 formed as above so that the upper part of the source electrode 145 or the drain electrode 150 is exposed by the second via hole.

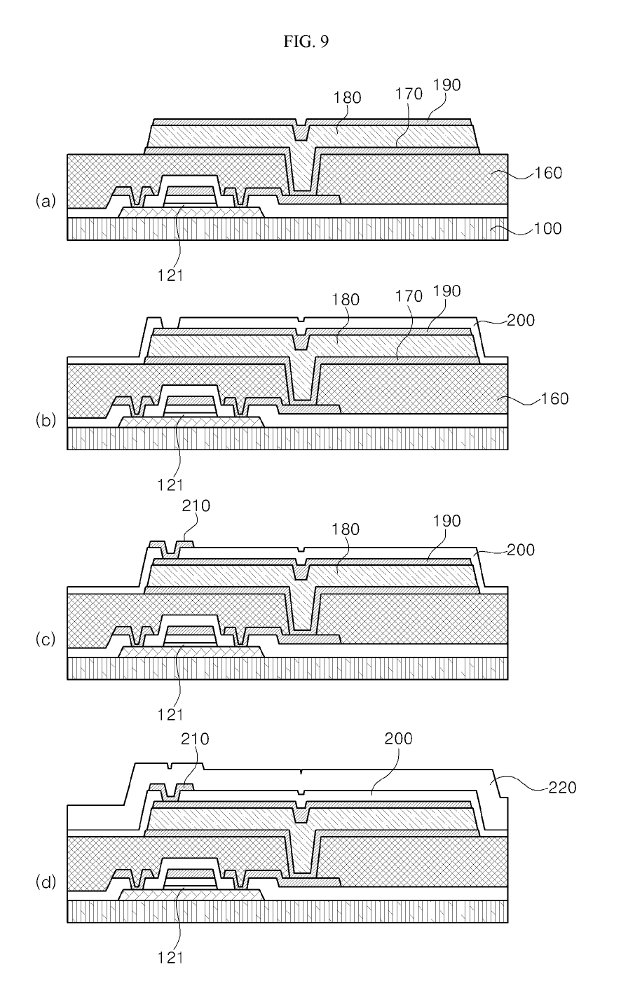

After this, as illustrated in (a) of FIG. 9, the first electrode 170 connected to the source electrode 145 or the drain electrode 150 is formed on the insulating layer 160, and then, the second electrode 190 is again formed in the upper part of the semiconductor layer 180 by forming the semiconductor layer 180 on the first electrode 170, thereby patterning the semiconductor layer 180.

As illustrated in (b) of FIG. 9, the first protective film 200 is formed in the upper part of the patterned semiconductor layer 180, as illustrated in (c) of FIG. 9, the common electrode 210 is formed on the first protective film 200, and as illustrated in (d) of FIG. 9, the second protective film 220 is again formed in the upper part of the common electrode 210.

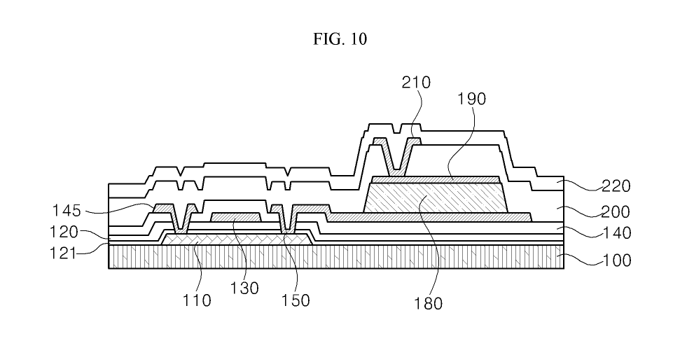

FIG. 10 is a cross-sectional view of an image sensor for an X-ray according to still another embodiment of the present invention.

As illustrated in FIG. 10, the image sensor may include: the semiconductor active layer 110 formed on the insulating substrate 100; the gate insulating film 120 formed to cover the semiconductor active layer 110; the gate electrode 130 formed on the gate insulating film 120; the interlayer insulating film 140 formed on the gate electrode 130; the source electrode 145 and the drain electrode 150 formed on the first via hole of the interlayer insulating film 140; and the photo diode configured to use an electrode extended from the drain electrode 150 as the first electrode.

At this time, the buffer film may be further formed between the insulating substrate 100 and the semiconductor active layer 110, and the insulating substrate 100 may be formed by coating an insulating film on an insulating material substrate or a metal substrate, and the semiconductor active layer 110 may be formed in an amorphous structure and in a thickness of 5 nm to 100 nm. Also, the gate insulating film 120 may be made of a silicon oxide film, and the buffer film may be made of any one of a silicon oxide film, a silicon oxynitride film and a silicon nitride film, or a mixture formed of at least two of them.

Meanwhile, unlike the embodiments of FIG. 2 and FIG. 6, in the embodiment of FIG. 10, the photo diode is configured to use an electrode extended from the source electrode 145 or the drain electrode 150 as the first electrode and not to have a planarization insulating film.

Also, the photo diode in the embodiment of FIG. 10 may be configured to include: the semiconductor layer 180 formed in the upper part of the first electrode which is the electrode extended from the source electrode 145 or the drain electrode 150; the second electrode 190 formed on the semiconductor layer 180; the first protective film 200 formed on the second electrode 190; and the common electrode 210 formed to be connected to the second electrode 190, and the second protective film 220 may be again formed in the upper part of the first protective film 200 and the common electrode 210. At this time, the semiconductor layer 180 of the photo diode may be made of amorphous silicon, and may include the P-type semiconductor layer, the intrinsic semiconductor layer and the N-type semiconductor layer.

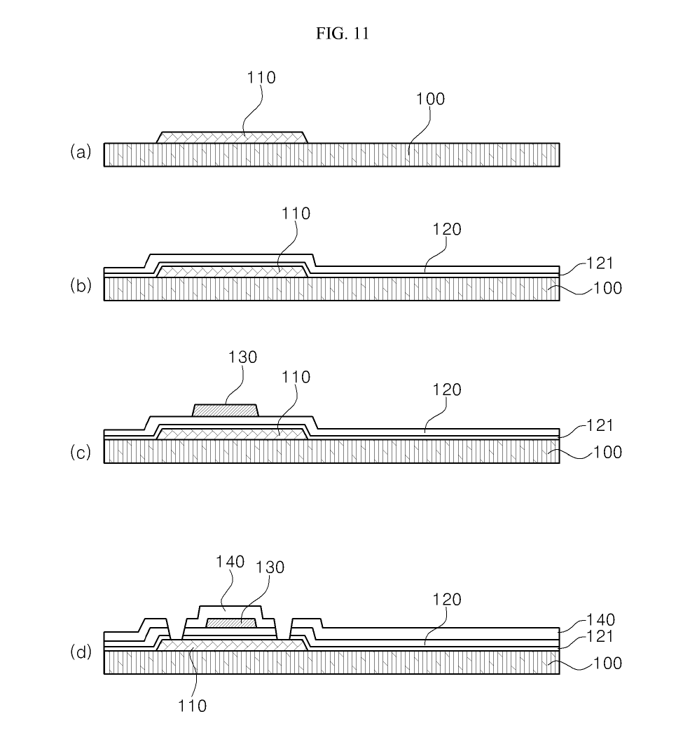

FIG. 11 through FIG. 13 are views illustrating a method of manufacturing the image sensor for the X-ray according to still another embodiment of the present invention.

Hereinafter, a method of manufacturing the image sensor for the X-ray according to the still another embodiment of the present invention will be explained with reference to FIG. 11 to FIG. 13.

When manufacturing the image sensor for the X-ray according to the still another embodiment of the present invention, as illustrated in (a) of FIG. 11, the semiconductor active layer 110 is formed on the insulating substrate 100, and as illustrated in (b) of FIG. 11 the gate insulating film 120 is formed on the semiconductor active layer 110 and the insulating substrate 100.

At this time, upon the forming of the gate insulating film 120 on the semiconductor active layer 110, the protective layer 121 made of the same material as that of the gate insulating film 120 may be formed in the upper part of the semiconductor active layer, and the gate insulating film 120 may be again formed in the upper part of the protective layer 121.

After this, as illustrated in (c) of FIG. 11, the gate electrode 130 is formed on the gate insulating film 120, and as illustrated in (d) of FIG. 11, the interlayer insulating film 140 is formed on the gate electrode 130, and the first via hole is formed in the interlayer insulating film 140. At this time, the first via hole is formed to pass through the gate insulating film 120 so that the upper surface of the semiconductor active layer 110 is exposed.

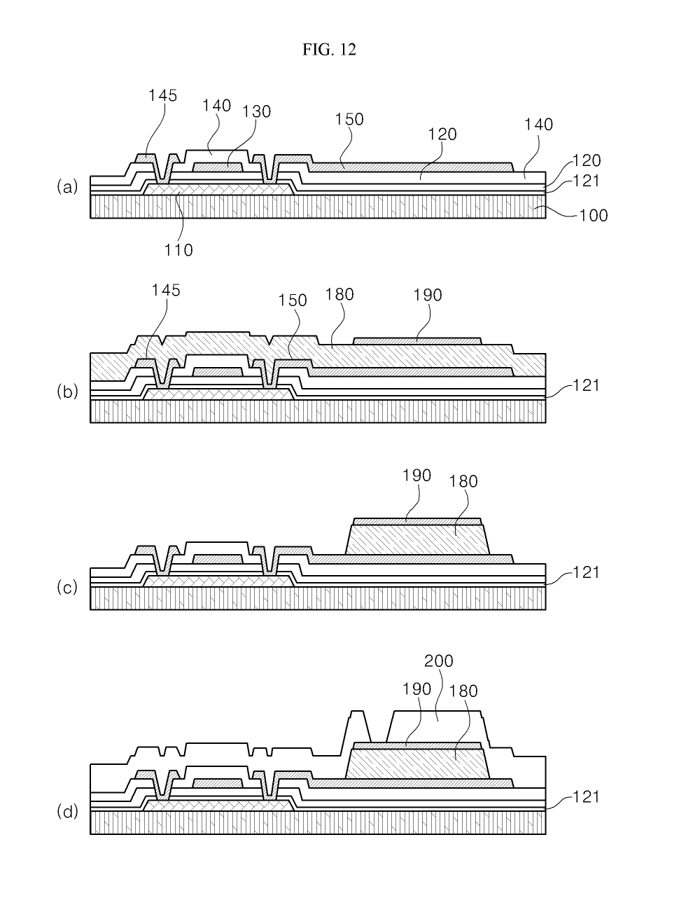

As illustrated in (a) of FIG. 12, the source electrode 145 and the drain electrode 150 are formed on the first via hole formed as above, and as illustrated in (b) of FIG. 12, the semiconductor layer 180 is formed on the source electrode 145 and the drain electrode 150, and the second electrode 190 is formed in the upper part of the semiconductor layer 180.

As illustrated in (c) of FIG. 12, the semiconductor layer 180 is patterned, and as illustrated in (d) of FIG. 12, the first protective film 200 is formed in the upper part of the second electrode 190.

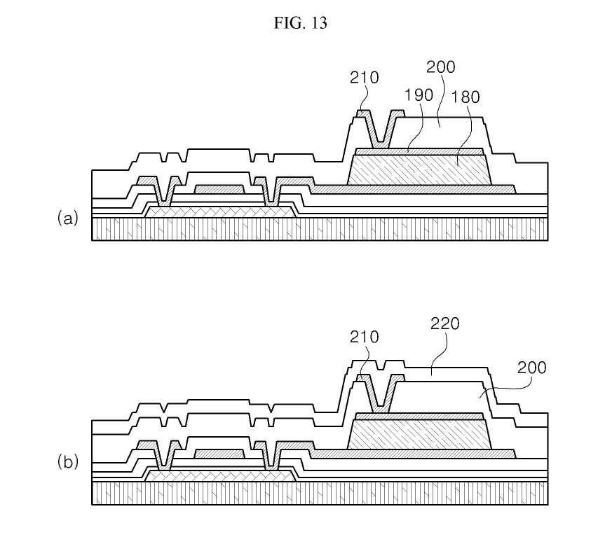

Also, as illustrated in (a) of FIG. 3, the common electrode 210 is formed on the first protective film 200, and as illustrated in (b) of FIG. 13, the second protective film 200 is again formed in the upper part of the common electrode 210, thereby configuring the image sensor for the X-ray.

The embodiments are disclosed in the drawings and the specification. The specific terms used herein are for the purpose of describing particular embodiments only and are not intended to be limiting of example embodiments. Thus, in the detailed description of the invention, having described the detailed exemplary embodiments of the invention, it should be apparent that modifications and variations can be made by persons skilled without deviating from the spirit or scope of the invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims and their equivalents.

1. An image sensor for an X-ray, comprising:
a semiconductor active layer formed on an insulating substrate;
a gate insulating film on the semiconductor active layer;
a gate electrode formed on the gate insulating film;
an interlayer insulating film which is formed on the gate electrode and in which a first via hole is formed;
a source electrode formed on the first via hole;
a drain electrode formed on the first via hole;
a first electrode formed to be connected to the source electrode or the drain electrode; and
a photo diode formed on the first electrode.

2. The image sensor of claim 1, wherein the photo diode comprises: a semiconductor layer formed on the first electrode; a second electrode formed on the semiconductor layer; and a common electrode formed to be connected to the second electrode.

3. The image sensor of claim 1, further comprising a buffer film formed between the insulating substrate and the semiconductor active layer.

4. The image sensor of claim 1, further comprising an insulating layer which is formed on the source electrode and the drain electrode and in which a second via hole is formed, wherein the first electrode is formed to be connected to the source electrode or the drain electrode via the second via hole.

5. The image sensor of claim 1, wherein the semiconductor active layer is made of any one of ZnO (Zinc Oxide), GZO (Gallium Zinc Oxide), IZO (Indium Zinc Oxide), ITO (Indium Tin Oxide), and IGZO (Indium Gallium Zinc Oxide).

6. The image sensor of claim 1, wherein the semiconductor active layer is formed in an amorphous structure.

7. The image sensor of claim 1, wherein the semiconductor active layer is formed in a thickness of 5 nm to 100 nm.

8. The image sensor of claim 1, wherein the gate insulating film is a silicon oxide film.

9. The image sensor of claim 1, wherein the gate insulating film is formed in the same size as that of the gate electrode.

10. The image sensor of claim 3, wherein the buffer film is made of any one of a silicon oxide film, a silicon oxynitride film and a silicon nitride film, or a mixture formed of at least two of them.

11. The image sensor of claim 1, wherein the insulating substrate is formed by coating an insulating film on an insulating material substrate or a metal substrate.

12. The image sensor of claim 2, wherein the semiconductor layer of the photo diode comprises a P-type semiconductor layer, an intrinsic semiconductor layer, and an N-type semiconductor layer.

13. The image sensor of claim 2, wherein the semiconductor layer of the photo diode is composed of amorphous silicon.

14. A method of manufacturing an image sensor for an X-ray, the method comprising:
forming a semiconductor active layer on an insulating substrate;
forming a gate insulating film on the semiconductor active layer;
forming a gate electrode on the gate insulating film;
forming an interlayer insulating film on the gate electrode and forming a first via hole in the interlayer insulating film;
forming a source electrode and a drain electrode on the first via hole;
forming a first electrode connected to the source electrode or the drain electrode; and
forming a photo diode on the first electrode.

15. The method of claim 14, wherein the forming of the photo diode on the first electrode comprises: forming a semiconductor layer on the first electrode; forming a second electrode on the semiconductor layer; and forming a common electrode to be connected to the second electrode.

16. The method of claim 14, wherein the forming of the semiconductor active layer on the insulating substrate comprises: forming a buffer film on the insulating substrate; and forming the semiconductor active layer on the buffer film.

17. The method of claim 14, wherein the forming of the semiconductor active layer on the insulating substrate further comprises thermally treating the semiconductor active layer within any one of oxygen gas, nitrogen gas, helium gas and argon gas, or a mixed gas formed of at least two of them at a temperature of 200 to 600.

18. The method of claim 14, wherein the forming of the gate insulating film on the semiconductor active layer comprises: forming a protective layer made of the same material as that of the gate insulating film in an upper part of the semiconductor active layer; and forming the gate insulating film in an upper part of the protective layer.

19. The method of claim 14, further comprising: forming an insulating layer on the source electrode and the drain electrode, and forming a second via hole in the insulating layer.

20. The method of claim 19, wherein the forming of the first electrode connected to the source electrode or the drain electrode is performed by forming the first electrode to be connected the source electrode or the drain electrode via the second via hole.

21. The method of claim 19, wherein the gate insulating film is formed in the same size as that of the gate electrode.
